(19) United States
(12) Patent Application Publication
(10) Pub. No.: US 2018/0168076 A1
(43) Pub. Date: Jun. 14, 2018

(54) STRETCHABLE AND/OR FLEXIBLE EMI SHIELDS AND RELATED METHODS

(71) Applicant: Laird Technologies, Inc., Chesterfield, MO (US)

(72) Inventors: Kuo Chun Chao, New Taipei City (TW); Mohammadali Khorrami, Foxboro, MA (US); Paul Francis Dixon, Sharon, MA (US)

(21) Appl. No.: 15/859,951

(22) Filed: Jan. 2, 2018

Related U.S. Application Data
(63) Continuation of application No. PCT/US2016/040638, filed on Jul. 1, 2016.
(60) Provisional application No. 62/188,173, filed on Jul. 2, 2015.
(60) Provisional application No. 62/326,933, filed on Apr. 25, 2016.

(51) Int. Cl. H05K 9/00; H05K 1/02; H05K 1/18; H05K 3/30

(52) U.S. Cl. CPC H05K 9/0022; H05K 1/028; H05K 1/0216; H05K 2201/10371; H05K 3/303; H05K 2201/10015; H05K 2201/1003; H05K 1/181

(57) ABSTRACT

According to various aspects, exemplary embodiments are disclosed of stretchable and/or flexible electromagnetic interference (EMI) shields. In an exemplary embodiment, a shield generally includes a stretchable and/or flexible shielding layer including a first side and a second side. One or more adhesion and/or dielectric layers are along at least the first side and/or the second side of the stretchable and/or flexible shielding layer.

### CROSS-REFERENCE TO RELATED APPLICATIONS

This application is a U.S. Continuation of PCT International Application No. PCT/US2016/040638 filed Jul. 1, 2016 (published as WO 2017/00486 on Jan. 5, 2017), which in turn, claims priority to and the benefit of U.S. Provisional Patent Application No. 62/188,173 filed Jul. 2, 2015 and U.S. Provisional Patent Application No. 62/326,933 filed Apr. 25, 2016. The entire disclosures of the above applications are incorporated herein by reference.

### FIELD

The present disclosure generally relates to stretchable and/or flexible electromagnetic interference (EMI) shields and related methods.

### BACKGROUND

This section provides background information related to the present disclosure which is not necessarily prior art.

A common problem in the operation of electronic devices is the generation of electromagnetic radiation within the electronic circuitry of the equipment. Such radiation may result in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable.

A common solution to ameliorate the effects of EMI/RFI is through the use of shields capable of absorbing and/or reflecting and/or redirecting EMI energy. These shields are typically employed to localize EMI/RFI within its source, and to insulate other devices proximal to the EMI/RFI source.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) broadly includes and refers to mitigating (or limiting) EMI and/or RFI, such as by absorbing, reflecting, blocking, and/or redirecting the energy or some combination thereof so that it no longer interferes, for example, for government compliance and/or for internal functionality of the electronic component system.

### DRAWINGS

The drawings described herein are for illustrative purposes only of selected embodiments and not all possible implementations, and are not intended to limit the scope of the present disclosure.

FIGS. 1A and 1B illustrate two stretchable and/or flexible shielding covers according to exemplary embodiments;

FIG. 2 illustrates a stretchable and/or flexible shielding cover being positioned over a component on a substrate according to an exemplary embodiment;

FIG. 3A illustrates a stretchable and/or flexible shielding cover being positioned over a plurality of components on a substrate according to an exemplary embodiment;

FIG. 3B illustrates the stretchable and/or flexible shielding cover shown in FIG. 3A after it has been positioned over the plurality of components on the substrate;

FIGS. 4A, 4B, 4C, and 4D are perspective views of female and male connectible grounding elements, respectively, that may be used with a stretchable and/or flexible shielding cover according to exemplary embodiments;

FIG. 5A illustrates a stretchable and/or flexible shielding cover being positioned over a plurality of components on a substrate according to an exemplary embodiment;

FIG. 5B illustrates the stretchable and/or flexible shielding cover shown in FIG. 5A after it has been positioned over the plurality of components on the substrate;

FIG. 6A illustrates a stretchable and/or flexible shielding cover being positioned over a plurality of components on a substrate according to an exemplary embodiment;

FIG. 6B illustrates the stretchable and/or flexible shielding cover shown in FIG. 6A after it has been positioned over the plurality of components on the substrate

FIG. 7A illustrates a substrate including a plurality of components and a grounding element according to an exemplary embodiment;

FIG. 7B illustrates the substrate of FIG. 7A after a stretchable and/or flexible shielding cover has been applied to the substrate with a grounding connection therebetween according to an exemplary embodiment;

FIG. 8 illustrate a stretchable and/or flexible shielding cover on a substrate being bent or flexed according to an exemplary embodiment;

FIG. 9 illustrates a connectible grounding element or female contact that may be used with a stretchable and/or flexible shielding cover according to exemplary embodiments;

FIG. 10 is an exemplary line graph of shielding effectiveness in decibels versus frequency from 30 Megahertz (MHz) to 40 Gigahertz (GHz) for a stretchable and/or flexible shielding cover comprising silver plated nylon/spandex fabric according to an exemplary embodiment, where the shielding effectiveness was measured before the silver plated nylon/spandex fabric was stretched and after the silver plated nylon/spandex fabric was stretched; and

FIG. 11 is a perspective view of a stretchable and/or flexible shielding cover and a L-C resonator according to an exemplary embodiment.

### DETAILED DESCRIPTION

Example embodiments will now be described more fully with reference to the accompanying drawings.

Disclosed herein are exemplary embodiments of stretchable and/or flexible electromagnetic (EMI) shielding, such as a board level shield (BLS) that includes one or more stretchable and/or flexible portions (e.g., a stretchable and/or flexible shielding cover or lid, etc.). In various exemplary embodiments, an EMI shield includes an electrically-conductive shielding cover or lid (broadly, a top or upper surface). The shielding cover comprises stretchable and/or flexible material(s) (e.g., a stretchable and/or flexible composite material, etc.) such that the shielding cover is thus stretchable and/or flexible. In some exemplary embodiments, the shielding cover may be applied and/or attached to portions of a substrate (e.g., printed circuit board, flexible circuit, etc.) so as to cover one or more components (e.g., board mounted PCB electronic components, etc.) on the substrate. By way of example, the shielding cover may be flexed, stretched, and/or shaped while under heat, pressure, etc., so as to cover one or more components on a substrate and with portions of the shielding cover in contact or connected with portions of the substrate. In some exemplary embodiments, a shielding cover is configured (e.g., sized, shaped, etc.) to extend over component(s) on a substrate and also to define one or more individual EMI shielding compartments for the component(s) on the substrate. In some exemplary embodiments, a shielding cover is positioned over a plurality of components on a substrate and is attached (e.g., adhesively bonded, anchored, etc.) to one or more portions of the substrate that are between at least two of the components being covered by the shielding cover. The positioning and attachment of the shielding cover may be performed, e.g., to shape the shielding cover into two or more EMI individual shielding compartments on the substrate such that components on the substrate are positioned within different ones of the shielding compartments.

In various exemplary embodiments, a stretchable and/or flexible shielding cover may be brought into contact with one or more electrically-conductive grounding contacts on a substrate. In some exemplary embodiments, a stretchable and/or flexible shielding cover may include one or more electrically-conductive grounding contacts. The one or more electrically-conductive grounding contacts of the shielding cover may be configured for connection with corresponding contact(s) on a substrate. In other exemplary embodiments, the shielding cover may include one or more L-C resonators that are configured to resonate at a resonant frequency and that are operable for virtually connecting to a ground plane, e.g., without using grounding vias or electrically-conductive grounding contacts, etc. Each L-C resonator may include an inductor and a capacitor.

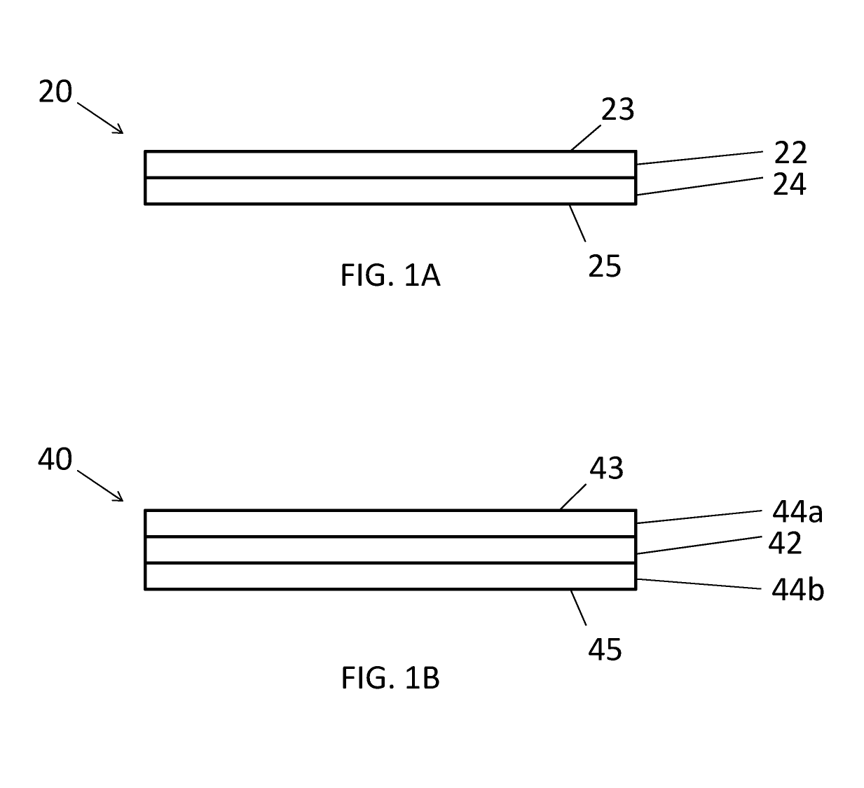

With reference to the figures, FIG. 1A illustrates an exemplary embodiment of a stretchable and/or flexible shielding cover 20 embodying one or more aspects of the present disclosure. The shielding cover 20 comprises stretchable and/or flexible material(s) (e.g., a stretchable and/or flexible composite material, etc.) such that the shielding cover 20 is also stretchable and/or flexible. The shielding cover 20 includes a shielding layer 22 along or on an adhesion and/or electrically insulating or dielectric layer 24. Stated differently, the adhesion and/or electrically insulating or dielectric layer 24 is along or on the first or lower side of the shielding layer 22.

The upper side or surface 23 of the stretchable and/or flexible shielding cover 20 defined by the shielding layer 22 is electrically conductive in this exemplary embodiment. The lower side or surface 25 of the stretchable and/or flexible shielding cover 20 defined by the layer 24 is dielectric or electrically insulating in embodiments in which the layer 24 is dielectric or electrically insulating. In such embodiments, the dielectric layer 24 may inhibit or prevent portions of the shielding cover's lower side or surface 25 from electrically shorting components received under the shielding cover 20.

The shielding layer 22 may be made, e.g., from electrically-conductive fabric, etc. Such fabric may be stretchable, conformable, and/or flexible (e.g., elongation greater than 250 percent (%) in the machine direction at 3 pound force per inch (lbf/in) width (ASTM D4964 mod), etc.). In various embodiments, the shielding layer 22 may be made from metal plated fabric or film, etc. In some embodiments, a single-sided electrically-conductive fabric may be used. The shielding layer 22 may comprise a silver plated stretchable fabric, such as a silver plated stretchable nylon knit material with anti-tarnish coating. The silver plated stretchable fabric may be RoHS/REACH compliant, Halogen-free per IEC-61249-2-21 standard, have a surface resistivity of less than 2 ohms per square (nominal), a maximum operation temperature of about 90 degrees Celsius, a minimum operation temperature of about negative 40 degrees Celsius, and an operating temperature range of negative 40 degrees Celsius to 90 degrees Celsius. The silver plated stretchable fabric may have a far field shielding effectiveness of about 48 decibels from 30 MHz to 300 MHz, about 50 decibels from 300 MHz to 3 GHz, and about 44 decibels from 3 GHz to 30 G0 GHz. The silver plated stretchable fabric may comprise a substrate that is 78% nylon/22% spandex and a metal plating that is 99% pure silver, such that the resulting plated material is stretchable (e.g., elongation greater than 250% in the machine direction at 3 lbf/inch width (ASTM D4964 mod), etc.). The silver plated stretchable fabric may be considered halogen-free per International Electrotechnical Commission (IEC) International Standard IEC 61249-2-21 (page 15, November 2003, First Edition). International Standard IEC 61249-2-21 defines “halogen free” (or free of halogen) for Electrical and Electronic Equipment Covered Under the European Union's Restriction of Hazardous Substances (RoHS) directive as having no more than a maximum of 900 parts per million chlorine, no more than a maximum of 900 parts per million bromine, and no more than a maximum of 1,500 parts per million total halogens. The phrases “halogen free,” “free of halogen,” and the like are similarly used herein.

Properties of an example silver plated stretchable nylon/spandex fabric that may be used as a shielding layer (e.g., 22 (FIG. 1A), 42 (FIG. 1B), etc.) in exemplary embodiments are provided in the tables below. A silver plated stretchable nylon/spandex fabric having the properties disclosed herein may be suited for use in on-body medical sensors, antimicrobial wound care, performance monitoring clothing for sports and military applications, consumer wearable electronics, and other smart textile applications or markets including specialty, medical, military, performance sportswear, and/or wearable electronics markets.

### Physical Properties

| Item | Unit | Value | Advantage |
|---|---|---|---|
| Substrate | 78% Nylon/ | | Stretchable, |
| | 22% Spandex | | Conformable |
| Metal Plating | 99% Pure Silver | | Antimicrobial, |
| | | | Hypoallergenic |
| Fabric Weight | Oz/yd2 (g/m²⁾ | 4.0 (136) | Light Weight |
| (nominal) | | | |
| Thickness (nominal) | Inch (mm) | 0.018 (0.45) | Flexible |
| Temperature Range | ° C. | −40° to 90° | |

### Electrical Properties

| Item | Unit | Value |
|---|---|---|
| Surface Resistivity (ASTM F390) | ohms/square | <2.0 |
| Far-Field Shielding (MIL-DTL-83528C) | effectiveness | (typical) |
| 30 MHz to 300 MHz | dB | 48 |
| 300 MHz to 3 GHz | dB | 50 |
| 3 GHz to 30 GHz | dB | 44 |

### Mechanical Properties

| Item | Unit | Value |
|---|---|---|
| Elongation at 3 lbf/inch width, Machine Direction | (%) | >250 |
| (ASTM D4964 mod) | | |

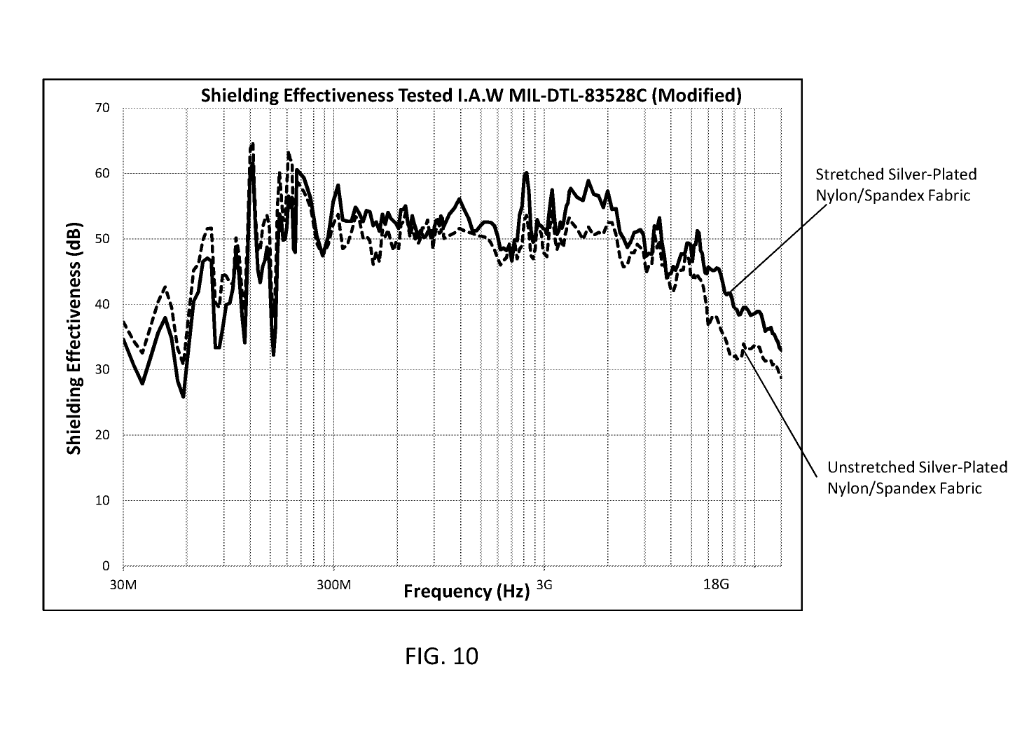

FIG. 10 is an exemplary line graph of shielding effectiveness in decibels versus frequency from 30 Megahertz (MHz) to 40 Gigahertz (GHz) for a 78% Nylon/22% spandex fabric plated with 99% pure silver according to an exemplary embodiment. The shielding effectiveness was measured for a 22 inch by 22 inch test specimen of the silver plated nylon/spandex fabric before it was stretched. The broken line shows the shielding effectiveness measured for the unstretched 22 inch by 22 inch test specimen of the silver plated nylon/spandex fabric. The test specimen was then stretched to 24 inches by 24 inches. The solid line shows the shielding effective measured for the stretched 24 inch by 24 inch test specimen of the silver plated nylon/spandex fabric. Generally, FIG. 10 shows that the silver plated nylon/spandex fabric may be stretched from 22″ by 22″ to 24″ by 24″ without any significant reduction in shielding effectiveness. These test results are provided for illustration purposes only as the stretchable and/or flexible shielding covers in other exemplary embodiments may be configured differently, such as having a different shielding effectiveness and/or being made from different materials besides silver, nylon, and/or spandex.

The adhesion and/or electrically insulating layer 24 may be made, e.g., from insulation adhesive, thermoplastic polyurethane (TPU), hot melt adhesive, epoxy, etc. In some embodiments, the adhesion and/or insulating layer 24 may be made from dielectric or electrically non-conductive hot melt polyethylene vinyl acetate (PEVA) adhesive film.

Thermal management and/or other functions may be provided for in various embodiments. For example, the shielding layer 22 and the layer 24 may be thermally conductive. In which case, the shielding cover 20 may help define or establish a portion of a thermally-conductive heat path along which heat may be transferred (e.g., conducted, etc.) from a heat source (e.g., one or more electronic components, one or more heat generating components, central processing unit (CPU), die, semiconductor device, etc.) through the shielding cover 20 to a heat removal/dissipation structure or component (e.g., a heat spreader, a heat sink, a heat pipe, a device exterior case or housing, etc.). As another example, the layer 24 may comprise a waterproof adhesive tape so as to provide a waterproof function.

FIG. 1B illustrates another exemplary embodiment of a stretchable and/or flexible shielding cover 40 embodying one or more aspects of the present disclosure. The shielding cover 40 comprises stretchable and/or flexible material(s) (e.g., a stretchable and/or flexible composite material, etc.) such that the shielding cover 40 is also stretchable and/or flexible. The shielding cover 40 includes a shielding layer 42 and adhesion and/or electrically insulating or dielectric layers 44a and 44b along or on opposite first and second (or lower and upper) sides or surfaces of the shielding layer 42. Stated differently, the shielding layer 42 is sandwiched between the adhesion and/or electrically insulating or dielectric layers 44a, 44b.

Accordingly, both of the upper and lower opposite sides or surfaces 43 and 45 of the stretchable and/or flexible shielding cover 40 defined respectively by the layers 44a, 44b are dielectric or electrically insulating in embodiments in which the layers 44a, 44b are dielectric or electrically insulating. In such embodiments, the dielectric layers 44a, 44b may inhibit or prevent portions of the shielding cover's upper and lower sides or surfaces 43, 45 from electrically shorting adjacent electronic components.

The shielding layer 42 may be made, e.g., from electrically-conductive fabric, etc. Such fabric may be stretchable, conformable, and/or flexible (e.g., elongation greater than 250% in the machine direction at 3 lbf/inch width (ASTM D4964 mod), etc.). In various embodiments, the shielding layer 42 may be made from metal plated fabric or film, etc. In some embodiments, a single-sided electrically-conductive fabric may be used. By way of example, the shielding layer 42 may comprise a silver plated stretchable fabric (e.g., silver plated nylon/spandex fabric, etc.) as described above and/or having the properties in the three tables above.

The adhesion and/or insulating layers 44a and/or 44b may be made, e.g., from insulation adhesive, thermoplastic polyurethane (TPU), hot melt adhesive, epoxy, etc. In some embodiments, the adhesion and/or insulating layers 44a and/or 44b may be made from electrically non-conductive hot melt polyethylene vinyl acetate (PEVA) adhesive film. The adhesion and/or insulating layers 44a and/or 44b may or may not have the same composition, dimensions, functionality etc.

Thermal management and/or other functions may be provided for in various embodiments. For example, the shielding layer 42 and the layers 44a, 44b may be thermally conductive. In which case, the shielding cover 40 may help define or establish a portion of a thermally-conductive heat path along which heat may be transferred (e.g., conducted, etc.) from a heat source (e.g., one or more electronic components, one or more heat generating components, central processing unit (CPU), die, semiconductor device, etc.) through the shielding cover 40 to a heat removal/dissipation structure or component (e.g., a heat spreader, a heat sink, a heat pipe, a device exterior case or housing, etc.). As another example, the layers 44a and/or 44b may comprise a waterproof adhesive tape so as to provide a waterproof function.

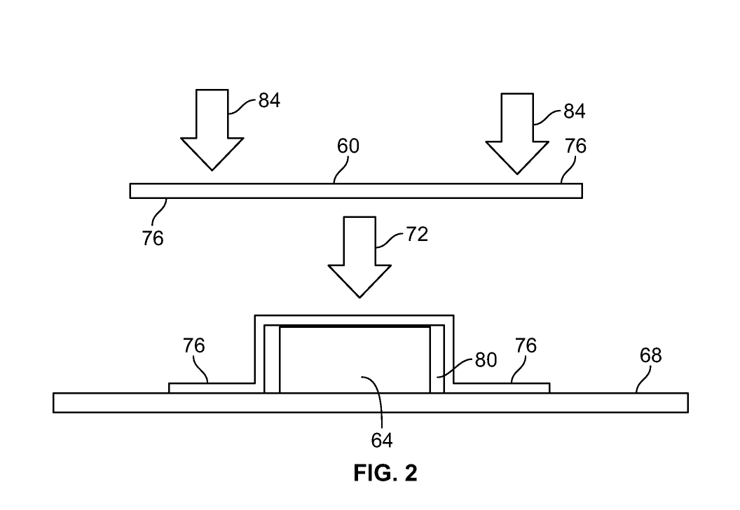

FIG. 2 shows an example stretchable and/or flexible shielding cover 60 that is generally planar, e.g., has no sidewalls, tilted edges, etc. The shielding cover 60 may be installed over an electronic component 64 on a substrate 68 (e.g., a printed circuit board (PCB), flexible printed circuit (FPC), etc.) in the following exemplary manner. As indicated by arrow 72, the shielding cover 60 may first be placed over the electronic component 64 such that edges 76 of the shielding cover 60 overhang the electronic component 64. The edges 76 of the shielding cover 60 may then be shaped (e.g., flexed, bent, formed, etc.) downward toward the substrate 68 for attachment to the substrate 68. After the edges 76 are attached to the substrate 68, the shielding cover 60 may form a shielding compartment 80 generally around the electronic component 64. By way of example, one or more processes involving heat, pressure, ultrasound, etc., may be used to shape the shielding cover 60 where indicated by arrows 84 such that the cover edges 76 extend downward toward and into contact with the substrate 68. The edges 76 of the shielding cover 60 then may be coupled or attached (e.g., anchored, joined, bonded via adhesive, etc.) to the substrate 68. For example, the edges 76 of the shielding cover 60 may be adhesively attached to the substrate 68 using an electrically-conductive adhesive (e.g., electrically-conductive pressure sensitive adhesive (PSA), etc.).

In some implementations, a heat press may be used to shape and/or connect a shielding cover with a substrate. In various implementations, the same process or different processes may be used to shape a shielding cover over component(s) and/or to bond the shielding cover to a substrate. Exemplary embodiments may include shielding covers having various configurations (e.g., circular, curved, triangular, irregular, other non-rectangular shapes, etc.).

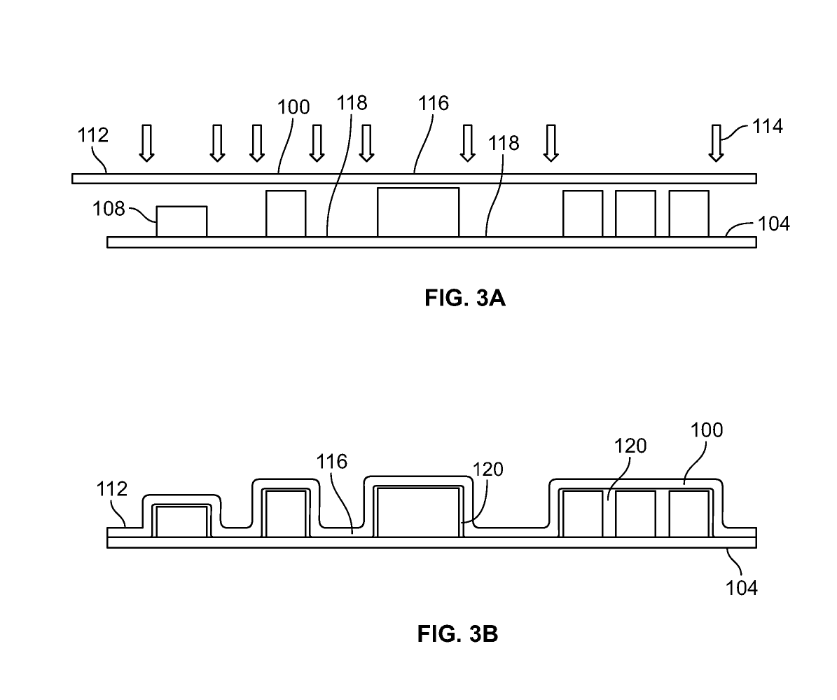

With reference to FIGS. 3A and 3B, an example stretchable and/or flexible shielding cover 100 may be attached to a substrate 104 over a plurality of electronic components 108 in accordance with the following example method. As shown in FIG. 3A, the shielding cover 100 may first be placed over the electronic components 108, e.g., such that edges 112 of the shielding cover 100 overhang the electronic components 108. The shielding cover's edges 112 and portions 116 may extend over selected substrate areas 118 between electronic components 108. The shielding cover's edges 112 and portions 116 may be shaped to extend downward toward the substrate 104. As shown in FIG. 3B, the shielding cover's edges 112 may be attached (e.g., adhesively bonded, etc.) to the substrate 104. The shielding cover's portions 116 may also be attached (e.g., adhesively bonded, etc.) to the substrate 104, e.g., in the substrate areas 118 between electronic components 108. With the attachment of the shielding cover 100 to the substrate 104, the shielding cover 100 may thus form individual EMI shielding compartments 120 around the electronic components 108.

By way of example, one or more processes involving, e.g., heat, pressure, ultrasound, combinations of the foregoing, etc., may be used to shape the shielding cover 100 where indicated in FIG. 3A by the arrows 114 such that the shielding's cover edges 112 and portions 116 extend toward and into contact with the substrate 104. The shielding cover's edges 112 and portions 116 may then be attached to the substrate 104. In various implementations, the same process or different processes may be used to shape a shielding cover and/or to bond a shielding cover to a substrate over electronic component(s). As shown in FIG. 3B, a given shielding compartment 120 can be formed over an individual component 108 or over multiple components 108.

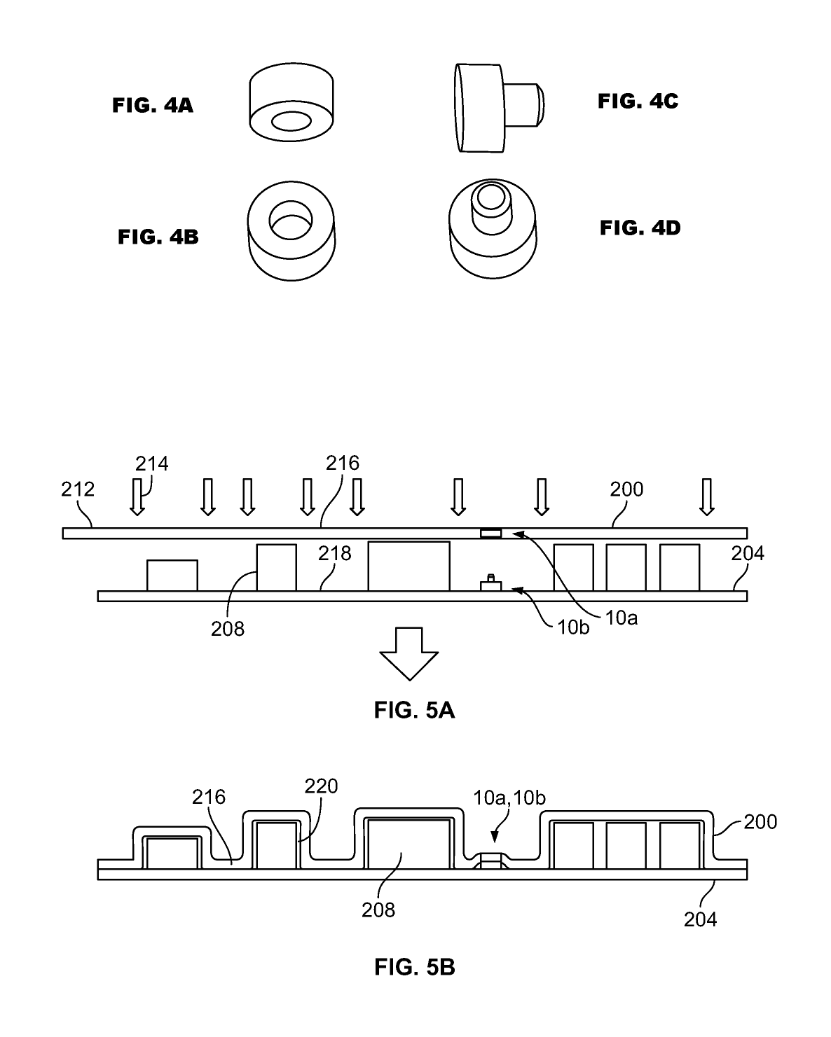

In various embodiments, stretchable and/or flexible shielding covers may be configured for electrical contact with grounding and/or other electrically-conductive contacts. FIG. 4 shows an example pair of contacts A and B that may be used for grounding of a shielding cover. The two pairs of contacts A and B shown in FIG. 4 may be made from metal, metal alloy, metalized material, or other electrically-conductive material. The example contact A is female and is configured for attachment to a shielding cover. By way of example, the example female contact A may be attached to the shielding cover by using an adhesive (e.g., instant glue, etc.) in an exemplary embodiment. In other exemplary embodiments, a contact may be attached to a shielding cover using alternative means or methods (e.g., buttoned or attached to a fabric similar to a button, etc.). The example contact B (FIG. 4) is male and is configured for attachment to a circuit board or other substrate. The contact B may, e.g., be soldered, welded, etc., onto a circuit board or other substrate.

The contacts A and B are examples only, and it will be understood by those knowledgeable in the art that various types of contacts and/or grounding could be used in various embodiments. For example, FIG. 9 shows a connectible grounding element or contact 510 according to another exemplary embodiment. In this alternative embodiment, the example contact includes a plurality of pointed projections or portions 511 (e.g., five circumferentially spaced apart portions or lances, etc.) protruding outwardly from the circular annular portion 513 of the example contact 510. The pointed projections 511 may be inserted into a fabric from a first side and bent (e.g., crimped, etc.) from a second side to thereby attach the contact 510 to the fabric.

With reference to FIGS. 5A and 5B, an example stretchable and/or flexible shielding cover 200 may be attached to a substrate 204 over a plurality of electronic components 208 in accordance with the following example method. As shown in FIG. 5A, the shielding cover 200 includes a contact 10a, and the substrate 204 includes a corresponding contact 10b. The shielding cover 200 is placed over the electronic components 208, e.g., such that edges 212 of the shielding cover 200 overhang the electronic components 208 and such that the contacts 10a and 10b are generally aligned with each other. The shielding cover's portions 216 extend over substrate areas 218 between electronic components 208. The shielding cover's edges 212 and portions 216 are shaped to extend downwardly toward the substrate 204. As shown in FIG. 5B, the shielding cover's edges 212 are attached (e.g., adhesively bonded, etc.) to the substrate 204. The shielding cover's portions 216 also are attached (e.g., adhesively bonded, etc.) to the substrate 204 in the substrate areas 218 between electronic components 208. With the attachment of the shielding cover 200 to the substrate 204, the shielding cover 200 forms shielding compartments 220 around the electronic components 208. Additionally, the contacts 10a and 10b are brought together and connected to each other.

By way of example, one or more processes involving, e.g., heat, pressure, ultrasound, combinations of the foregoing, etc., may be used to shape the shielding cover 200 where indicated in FIG. 5A by arrows 214 such that the shielding's cover edges 212 and portions 216 extend toward and into contact with the substrate 204. The shielding cover's edges 212 and portions 216 may then be attached to the substrate 204, and the contacts 10a and 10b may be connected with each other. In various implementations, the same process or different processes may be used to shape and/or attach a shielding cover to a substrate over electronic component(s) and/or to connect electrical contacts provided on the shielding cover and substrate. As shown in FIG. 5B, a given shielding compartment 220 can be formed over an individual component 208 or over multiple components 208.

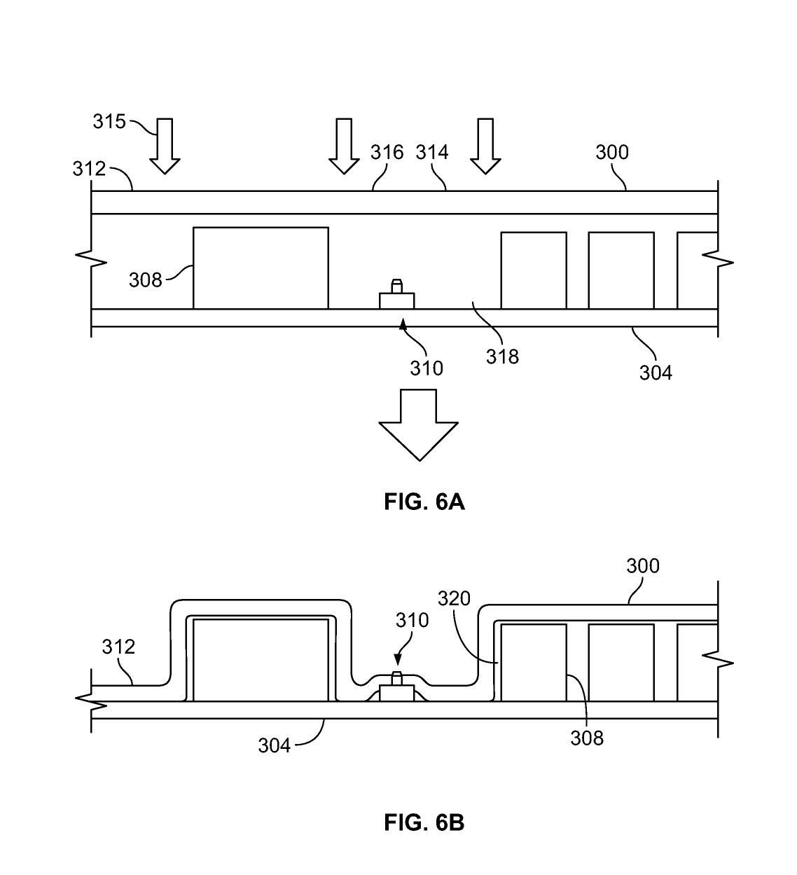

Embodiments also are possible in which an electrical contact is configured on a substrate for direct connection with a shielding cover. With reference to FIGS. 6A and 6B, an example stretchable and/or flexible shielding cover 300 may be attached to a substrate 304 over a plurality of electronic components 308 in accordance with the following example method. As shown in FIG. 6A, the substrate 304 includes an electrical contact 310 installed thereon. The shielding cover 300 is placed over the electronic components 308 such that edges 312 of the shielding cover 300 overhang the electronic components 308, and a shielding cover contact location 314 and the substrate contact 310 are generally aligned. As shown in FIG. 6A, the shielding cover's portion 316 extend over a substrate area 318 between electronic components 308. The shielding cover 300 may be shaped so that the edges 312 and portion 316 extend downwardly toward the substrate 304. As shown in FIG. 6B, the shielding cover edges 312 are attached (e.g., adhesively bonded, etc.) to the substrate 304. The shielding cover portion 316 also is attached (e.g., adhesively bonded, etc.) to the substrate 304 in the substrate area 318 between electronic components 308. With the attachment of the shielding cover 300 to the substrate 304, the shielding cover 300 forms shielding compartments 320 around the electronic components 308. Additionally, the shielding cover contact location 314 and substrate contact 310 are brought together and connected.

By way of example, one or more processes involving, e.g., heat, pressure, ultrasound, combinations of the foregoing, etc., may be used to shape the shielding cover 300, where indicated in FIG. 6A by arrows 315 such that the shielding cover's edges 312 and portion 316 extend toward and into contact with the substrate 304. The shielding cover's edges 312 and portion 316 may then be attached to the substrate 304. The shielding cover contact location 314 and substrate contact 310 may be connected with each other, e.g., in the course of attaching the substrate 304 with the shielding cover's portion 316 that includes the contact location 314. In various implementations, the same process or different processes may be used to shape and/or attach a shielding cover to a substrate over electronic component(s) and/or to connect electrical contacts provided on the shielding cover and substrate. As shown in FIG. 6B, when the shielding cover 300 is attached to the substrate 304, the shielding cover contact location 314 is brought into contact with the substrate contact 310. In the present example embodiment, the contact 310 is caused to pierce the shielding cover contact location 314 to achieve a grounding connection for the shielding cover 300. In some other embodiments, an electrical connection between a shielding cover and a contact on a substrate could be accomplished in other or additional ways. In various implementations, the same process or different processes may be used to shape and/or attach a shielding cover to a substrate over electronic component(s) and/or to make a grounding connection or other electrical connection between the shielding cover and substrate. As shown in FIG. 6B, a given shielding compartment 320 can be formed over an individual component 308 or over multiple components 308.

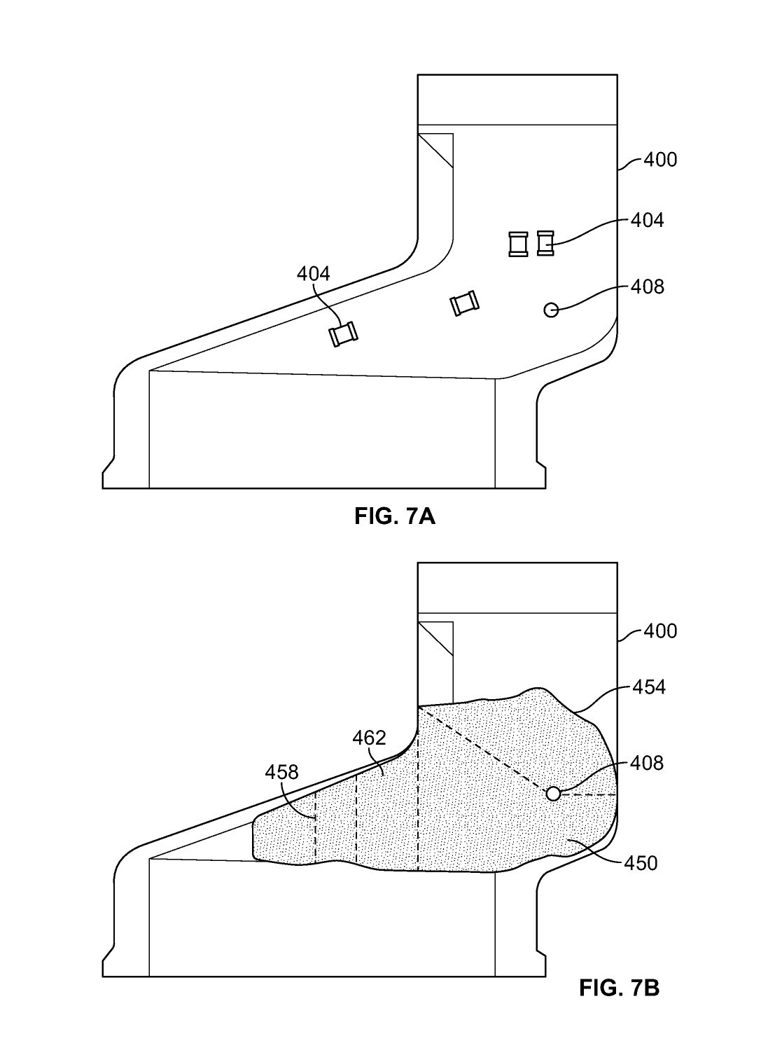

FIGS. 7A and 7B show an example substrate, i.e., a flexible printed circuit (FPC) 400, before and after being provided with a shielding cover. As shown in FIG. 7A, the FPC 400 includes a plurality of electronic components 404 and a metal grounding contact 408. As shown in FIG. 7B, an example stretchable and/or flexible shielding cover 450 is attached to the FPC 400 over the electronic components 404 and grounding contact 408. Edges 454 and portions 458 of the shielding cover 450 are attached (e.g., adhesively bonded, etc.) to the FPC 400. The shielding cover 450 is electrically connected with the FPC grounding contact 408. In this example, the example female contact A (FIG. 4) is attached to or fixed on the electrically-conductive fabric or shielding cover 450, and the example male contact B (FIG. 4) is attached to or fixed on the FPC 400. The example male and female contacts A and B may be attached by using adhesive (e.g., instant glue, etc.), buttoned (e.g., attached similar to a button on a shirt, etc.), or other suitable means and methods, etc.

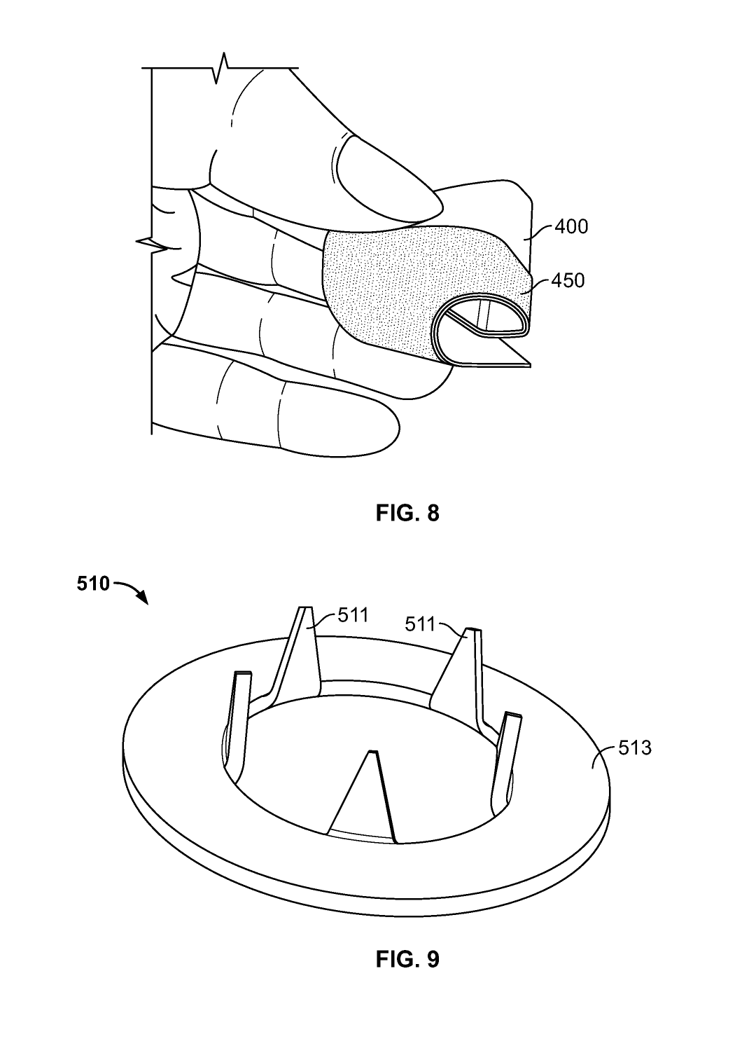

As shown by the broken lines 458 in FIG. 7B, the shielding cover 450 forms a plurality of compartments 462 on the FPC 400 for the electronic components 404. The grounding contact 408 is provided generally between compartments 462 e.g., where a portion 458 of the shielding cover 450 is bonded to the FPC 400. In some embodiments, traces of the bonding of a stretchable and/or flexible shielding cover to a substrate, such as a FPC, may be at least slightly visible on the back of the substrate. As shown by FIG. 8, the shielding cover 450 may be bent together with the FPC 400.

In exemplary embodiments, a stretchable and/or flexible shielding cover (e.g., 20 (FIG. 1A), 40 (FIG. 1B), 60 (FIG. 2), 100 (FIG. 3A), 200 (FIG. 5A), 300 (FIG. 6A), 450 (FIG. 7B), etc.) disclosed herein may be used with one or more L-C resonators. The one or more L-C resonators may be configured to resonate at a resonant frequency (e.g., about 2.75 GHz, about 4 GHz, etc.). The one or more L-C resonators may be operable for virtually connecting a shielding cover to a ground plane, e.g., without using grounding vias, etc. For example, the shielding cover may be positioned along a first side of a printed circuit board (PCB) and virtually connected via the one or more L-C resonators to a ground plane along the second side of the PCB without any physical electrical connection directly between the shielding cover and the ground plane.

Each L-C resonator may include an inductor and a capacitor. By way of example, the inductor may comprise an inductive pin, such as an electrically-conductive (e.g., metal, etc.) pin having a rectangular or circular cross section, etc. By way of further example, the capacitor may comprise a capacitive patch element, such as a generally rectangular electrically-conductive (e.g., metal, etc.) patch element. Alternatively, the L-C resonators may comprise differently configured inductors and capacitors, e.g., made of different materials, having different shapes (e.g., non-circular, non-rectangular, etc.).

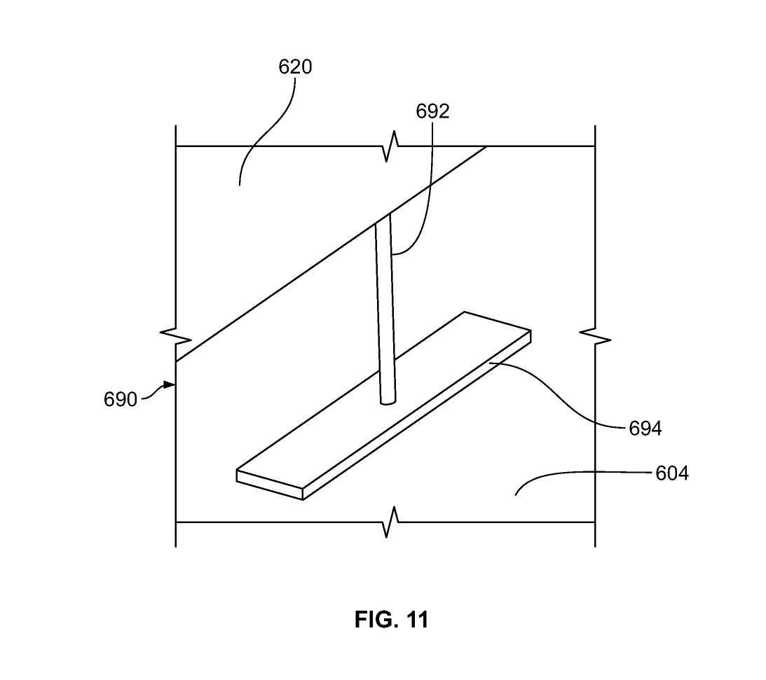

For example, FIG. 11 illustrates a portion of a stretchable and/or flexible shielding cover 620 and an L-C resonator 690 coupled (e.g., adhesively attached, etc.) to the shielding cover 620. The L-C resonator 690 may be configured to resonate at a resonant frequency (e.g., about 2.75 GHz, about 4 GHz, etc.). In exemplary embodiments, a sufficient number of L-C resonators 690 are coupled to the shielding cover 620 to provide or define a virtual ground fence or frame (VGF) that allows the shielding cover 620 to be virtually connectible to a ground plane underneath or along an opposite side of a PCB 604 (broadly, a substrate) without any physical electrical connection directly between the shielding cover 620 and the ground plane. For example, the shielding cover 620 may be virtually connected to the ground plane without using grounding vias, plated thru holes, or other intervening physical components to create a physically existing electrical pathway from the shielding cover 620 to the ground plane.

The one or more L-C resonators 690 may be coupled to the shielding cover 620 by an adhesive, e.g., a high-temperature adhesive, epoxy, electrically-conductive pressure sensitive adhesive (CPSA), electrically-conductive hot melt adhesive, etc. Other or additional adhesives and/or methods could also be used to attach an L-C resonator to a shielding cover. In some other exemplary embodiments, an L-C resonator may be bonded to a shielding cover by fused metal where the metal is fused by thermal energy (e.g., in a reflow process, etc.), by laser energy, etc.

The one or more L-C resonators 690 may be placed at predetermined locations and spaced apart from each other along the shielding cover 620 to provide or accommodate acceptable virtual grounding at their resonance frequency (e.g., about 2.75 GHz, etc.). In an exemplary embodiment, three L-C resonators 690 may be equally spaced apart from each other along each corresponding side of the shielding cover 620. The number, shape, and size of L-C resonators and their locations along the stretchable and/or flexible EMI shielding cover or member may depend on the configuration (e.g., shape, size, etc.) of the stretchable and/or flexible EMI shielding cover or member and the particular end use intended for the EMI shielding or BLS that includes the stretchable and/or flexible EMI shielding cover or member and L-C resonators. The number of resonators may be increased depending on the value of the required shielding effectiveness at the resonance frequency. Different resonator dimensions can also be used to spread the resonance frequencies in a wide range to achieve a wide band solution.

As shown in FIG. 11, the L-C resonator 690 includes an inductor 692 and a capacitor 694. The inductor 692 may comprise an elongate linear inductive element, such as an inductive pin having a rectangular or circular cross section, etc. The capacitor 694 may comprise a capacitive patch element, such as a generally rectangular electrically-conductive patch element, etc. The inductor 692 and capacitor 694 may be made of stainless steel, although other electrically-conductive materials may also be used (e.g., other metals, non-metals, etc.). The capacitors 694 may be fabricated directly on the PCB substrate 604, and the inductors 692 may be soldered to the capacitors 694. Alternatively, the capacitors 694 may be formed by other manufacturing processes, such as stamping, etc. Likewise, the inductors 692 may be coupled to the capacitors 694 using other means besides solder, such as electrically-conductive adhesives, etc.

The inductor 692 is coupled to the capacitor 694 such that the capacitor 694 is generally perpendicular to the inductor 692. In addition, the capacitor 694 may be configured to contact (e.g., abut against, be flush against, rest upon, etc.) the substrate 604 when the shielding cover 620 and L-C resonator 690 are installed to the substrate 604. Alternatively, the L-C resonators may comprise inductors and/or capacitors that have a different configuration, such as having different shapes (e.g., non-circular cross-section, non-rectangular shape, etc.) and/or being made of different materials, etc. For example, the inductive pins (broadly, inductors) may have any cross-section shape as long as the inductive pins are inductive enough to establish the resonance frequency at the correct or predetermined location with the aid of the capacitive patches (broadly, capacitors).

In various exemplary embodiments, electronic components are provided with EMI shielding by virtue of the EMI shielding inhibiting the ingress and/or egress of EMI into and/or out of compartment(s) defined by the stretchable and/or flexible EMI shielding cover. In other exemplary embodiments, a stretchable and/or flexible EMI shielding cover may be positioned over a plurality of components on a substrate and may be shaped so as to cover walls, dividers, and/or partitions previously provided between the components. In which case, components on the substrate may be positioned in different compartments such that the components are provided with EMI shielding by virtue of the EMI shielding compartments inhibiting the ingress and/or egress of EMI into and/or out of each EMI shielding compartment.

In various embodiments, a stretchable and/or flexible shielding cover may be sized, e.g., to overhang a perimeter defined by the outside dimensions of components to be covered by the shielding cover. A stretchable and/or flexible shielding cover may be attached to a substrate in various ways depending, e.g., on the materials used to make the shielding cover. In some embodiments, a stretchable and/or flexible shielding cover may be secured to a substrate by an adhesive, e.g., a high-temperature adhesive, epoxy, electrically-conductive pressure sensitive adhesive (CPSA), electrically-conductive hot melt adhesive, etc. Other or additional adhesives and/or methods could also be used to attach a shielding cover to a substrate. In some embodiments, a stretchable and/or flexible shielding cover may be bonded to a substrate by fused metal where the metal is fused by thermal energy (e.g., in a reflow process, etc.), by laser energy, etc.

Also disclosed are exemplary embodiments of methods relating to a stretchable and/or flexible electromagnetic interference (EMI) shield. In an exemplary embodiment, a method generally includes applying one or more adhesion and/or dielectric layers along at least a first side and/or a second side of a stretchable and/or flexible shielding layer to thereby provide the stretchable and/or flexible shield; and/or positioning the stretchable and/or flexible EMI shield over one or more components on a substrate, whereby the stretchable and/or flexible EMI shield is operable for providing EMI shielding for the one or more components under the stretchable and/or flexible EMI shield.

The method may include applying a dielectric layer along both the first side and the second side of the stretchable and/or flexible shielding layer. The method may include attaching the stretchable and/or flexible EMI shield to the substrate such that the one or more components on the substrate are under the stretchable and/or flexible EMI shield generally between the substrate and the dielectric layer along the first side of the stretchable and/or flexible shielding layer. The dielectric layer along the first side of the stretchable and/or flexible shielding layer may inhibit the stretchable and/or flexible shielding layer from directly contacting and electrically shorting the one or more components on the substrate that are under the stretchable and/or flexible EMI shield.

The method may include applying a dielectric layer along only the first side of the stretchable and/or flexible shielding layer. The method may also include attaching the stretchable and/or flexible EMI shield to the substrate such that the one or more components on the substrate are under the stretchable and/or flexible EMI shield generally between the dielectric layer and the substrate. The dielectric layer may inhibit the stretchable and/or flexible shielding layer from directly contacting and electrically shorting the one or more components on the substrate that are under the stretchable and/or flexible EMI shield.

The method may include providing one or more resonators that are configured to be operable for virtually connecting the stretchable and/or flexible EMI shield to a ground plane without any physical electrical connection directly between the ground plane and the stretchable and/or flexible EMI shield. Each of the one or more resonators may include an L-C resonator comprising an inductor and a capacitor. The method may include attaching the inductor to the stretchable and/or flexible EMI shield, and attaching the capacitor to the substrate. The inductor may be an inductive pin. The capacitor may be a capacitive patch. The method may include virtually connecting the stretchable and/or flexible EMI shield to the ground plane by using the one or more resonators and without using any physical electrical connection directly between the ground plane and the stretchable and/or flexible EMI shield.

The method may include positioning the stretchable and/or flexible EMI shield over one or more components along a first side of a printed circuit board such that the one or more resonators virtually connect the stretchable and/or flexible EMI shield to a ground plane along a second side of the printed circuit board.

The method may include shaping the stretchable and/or flexible EMI shield to define a plurality of individual EMI shielding compartments, such that different components on the substrate are positionable in different EMI shielding compartments and are provided with EMI shielding by virtue of the EMI shielding compartments inhibiting the ingress and/or egress of EMI into and/or out of each EMI shielding compartment. The method may include attaching the stretchable and/or flexible EMI shield to one or more portions of the substrate between at least two of the one or more components on the substrate.

The method may include grounding the stretchable and/or flexible EMI shield by bringing the stretchable and/or flexible EMI shield into contact with one or more electrically-conductive grounding contacts on the substrate; and/or by connecting a first electrically-conductive grounding contact of the substrate with a second electrically-conductive grounding contact of the stretchable and/or flexible EMI shield.

The method may further comprise attaching a first electrically-conductive grounding contact to the substrate; attaching a second electrically-conductive grounding contact to the stretchable and/or flexible EMI shield; and connecting the first and second electrically-conductive grounding contacts with each other to thereby ground the stretchable and/or flexible EMI shield.

The method may include attaching the stretchable and/or flexible EMI shield using one or more of the following: heat, pressure, a heat press, and ultrasound. The stretchable and/or flexible shielding layer may comprise one or more of the following: stretchable, conformable, and/or flexible fabric, electrically-conductive fabric, film, single-sided electrically-conductive fabric, a metal plated fabric, and a silver plated stretchable nylon knit material. The one or more adhesion and/or dielectric layers may comprise one or more of the following: insulation adhesive, thermoplastic polyurethane, hot melt adhesive, epoxy, and electrically non-conductive hot melt polyethylene vinyl acetate adhesive film.

The stretchable and/or flexible shielding layer may comprise a silver plated nylon/spandex fabric, and the one or more adhesion and/or dielectric layers comprise an electrically non-conductive hot melt polyethylene vinyl acetate adhesive film. The stretchable and/or flexible shielding layer may be configured to have an elongation greater than 250 percent in the machine direction at three pound force per inch width.

Exemplary embodiments of flexible electronic circuits are disclosed. In an exemplary embodiment, a flexible electronic circuit generally includes a flexible substrate and one or more components on the flexible substrate. A stretchable and/or flexible electromagnetic interference (EMI) shield is provided over the plurality of components. The stretchable and/or flexible electromagnetic interference (EMI) shield includes one or more adhesion and/or dielectric layers along at least a first side and/or a second side of a stretchable and/or flexible shielding layer. The stretchable and/or flexible EMI shield is positioned over the one or more components on the flexible substrate. The stretchable and/or flexible EMI shield is operable for providing EMI shielding for the one or more components under the stretchable and/or flexible EMI shield.

The stretchable and/or flexible electromagnetic interference (EMI) shield may be attached to one or more portions of the flexible substrate between at least two of the one or more components on the flexible substrate to thereby define a plurality of individual EMI shielding compartments, such that different components on the flexible substrate are positioned in different EMI shielding compartments and are provided with EMI shielding by virtue of the EMI shielding compartments inhibiting the ingress and/or egress of EMI into and/or out of each EMI shielding compartment.

The stretchable and/or flexible shielding layer may comprise a silver plated nylon/spandex fabric. The one or more adhesion and/or dielectric layers may comprise an electrically non-conductive hot melt polyethylene vinyl acetate adhesive film. The stretchable and/or flexible shielding layer may be configured to have an elongation greater than 250 percent in the machine direction at 3 pound force per inch width.

The one or more adhesion and/or dielectric layers may comprise a dielectric layer along both the first side and the second side of the stretchable and/or flexible shielding layer. The one or more components on the flexible substrate may be under the stretchable and/or flexible EMI shield generally between the flexible substrate and the dielectric layer along the first side of the stretchable and/or flexible shielding layer. The dielectric layer along the first side of the stretchable and/or flexible shielding layer may inhibit the stretchable and/or flexible shielding layer from directly contacting and electrically shorting the one or more components on the flexible substrate that are under the stretchable and/or flexible EMI shield.

The one or more adhesion and/or dielectric layers may comprise a dielectric layer along only the first side of the stretchable and/or flexible shielding layer. The one or more components on the flexible substrate may be under the stretchable and/or flexible EMI shield generally between the dielectric layer and the flexible substrate. The dielectric layer may inhibit the stretchable and/or flexible shielding layer from directly contacting and electrically shorting the one or more components on the flexible substrate that are under the stretchable and/or flexible EMI shield.

One or more resonators may be coupled to the stretchable and/or flexible EMI shield. The substrate may comprise a printed circuit board including a first side including the one or more components and a second side including a ground plane. The stretchable and/or flexible EMI shield may positioned over the one or more components along the first side of the printed circuit board. The one or more resonators may virtually connect the stretchable and/or flexible EMI shield to the ground plane along the second side of the printed circuit board. Each of the one or more resonators may include an L-C resonator comprising an inductor and a capacitor. The inductor may be attached to the stretchable and/or flexible EMI shield. The capacitor may be attached to the printed circuit board. The inductor may be an inductive pin. The capacitor may be a capacitive patch.

The substrate may include one or more electrically-conductive grounding contacts in contact with the stretchable and/or flexible EMI shield to thereby ground the stretchable and/or flexible EMI shield. The substrate may include a first electrically-conductive grounding contact connected with a second electrically-conductive grounding contact of the stretchable and/or flexible EMI shield to thereby ground the stretchable and/or flexible EMI shield. The stretchable and/or flexible shielding layer may comprise one or more of the following: stretchable, conformable, and/or flexible fabric, electrically-conductive fabric, film, single-sided electrically-conductive fabric, a metal plated fabric, and a silver plated stretchable nylon knit material. The one or more adhesion and/or dielectric layers may comprise one or more of the following: insulation adhesive, thermoplastic polyurethane, hot melt adhesive, epoxy, and electrically non-conductive hot melt polyethylene vinyl acetate adhesive film.

Also disclosed are exemplary embodiments of shields suitable for use in providing electromagnetic interference (EMI) shielding for one or more components on substrates. In an exemplary embodiment, a shield generally includes a stretchable and/or flexible shielding layer including a first side and a second side. One or more adhesion and/or dielectric layers are along at least the first side and/or the second side of the stretchable and/or flexible shielding layer. The shield further comprises one or more resonators configured to be operable for virtually connecting the shield to a ground plane without any physical electrical connection directly between the ground plane and the shield; and/or an electrically-conductive grounding contact connectible with an electrically-conductive grounding contact of the substrate to thereby ground the shield. The shield is positionable over the one or more components on the substrate such that the shield is operable for providing EMI shielding for the one or more components under the shield.

The stretchable and/or flexible shielding layer may comprise a silver plated nylon/spandex fabric. The one or more adhesion and/or dielectric layers may comprise an electrically non-conductive hot melt polyethylene vinyl acetate adhesive film. The stretchable and/or flexible shielding layer may be configured to have an elongation greater than 250 percent in the machine direction at three pound force per inch width.

The stretchable and/or flexible shielding layer may comprise one or more of the following: stretchable, conformable, and/or flexible fabric, electrically-conductive fabric, film, single-sided electrically-conductive fabric, a metal plated fabric, and a silver plated stretchable nylon knit material. The one or more adhesion and/or dielectric layers may comprise one or more of the following: insulation adhesive, thermoplastic polyurethane, hot melt adhesive, epoxy, and electrically non-conductive hot melt polyethylene vinyl acetate adhesive film.

The one or more adhesion and/or dielectric layers may comprise a dielectric layer along the first side and the second side of the stretchable and/or flexible shielding layer. The dielectric layer along the first side of the stretchable and/or flexible shielding layer may inhibit the stretchable and/or flexible shielding layer from directly contacting and electrically shorting the one or more components on the substrate that are under the stretchable and/or flexible EMI shield.

The one or more adhesion and/or dielectric layers may comprise a dielectric layer along only the first side of the stretchable and/or flexible shielding layer. The dielectric layer may inhibit the stretchable and/or flexible shielding layer from directly contacting and electrically shorting the one or more components on the substrate that are under the stretchable and/or flexible EMI shield.

The shield may include one or more resonators that comprise a plurality of L-C resonators each including an inductor and a capacitor. The L-C resonators may be configured to resonate at a predetermined resonant frequency. The inductor may be attached to the shield. The capacitor may be attached to the substrate. The inductor may be an inductive pin. The capacitor may be a capacitive patch.

The shield may include a female electrically-conductive grounding contact connectible with a corresponding male electrically-conductive grounding contact of the substrate to thereby ground the shield.

The shield may be configured to be attachable to one or more portions of the substrate between at least two of the one or more components on the substrate to thereby define a plurality of individual EMI shielding compartments, such that different components on the substrate are positionable in different EMI shielding compartments and thereby provided with EMI shielding by virtue of the EMI shielding compartments inhibiting the ingress and/or egress of EMI into and/or out of each EMI shielding compartment.

An electronic device may comprise an exemplary embodiment of a shield disclosed herein and a printed circuit board including a first side having one or more components and a second side having a ground plane. The shield may include a plurality of L-C resonators. The shield may be positioned relative to the printed circuit board such that the one or more components along the first side of the printed circuit board are under the shield and such that the L-C resonators virtually connect the shield to the ground plane along the second side of the printed circuit board.

Exemplary embodiments disclosed herein may provide one or more (but not necessarily any or all) of the following advantages or features over some existing board level EMI shields. For example, exemplary embodiments disclosed herein may be stretchable and/or flexible compared to conventional shielding (made, e.g., of rigid materials such as metal, etc.) and may exhibit the same or similar shielding effectiveness as rigid metal board-level shields. By way of example, a stretchable and/or flexible shield disclosed herein may be used with or on a rigid substrate. As another example, a stretchable and/or flexible board-level shielding cover disclosed herein may be used with or on a flexible substrate. In this latter example, the stretch capability and/or flexibility of the shielding cover may provide sufficient flexibility to allow the shielding cover to bend or twist along with the flexible substrate. Thus, the stretchable and/or flexible board-level shielding cover may continue to provide effective shielding when the shielding cover is stretched, flexed, bent, and/or twisted along with a flexible substrate on which the shielding cover is installed.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. The method relating to a stretchable and/or flexible electromagnetic interference (EMI) shield, the method comprising applying one or more adhesion and/or dielectric layers along at least a first side and/or a second side of an electrically-conductive fabric or film to thereby provide the stretchable and/or flexible EMI shield, whereby the electrically-conductive fabric or film including the one or more adhesion and/or dielectric layers applied along at least the first side and/or the second side of the electrically-conductive fabric or film are positionable over one or more components on a substrate for providing EMI shielding for the one or more components under the stretchable and/or flexible EMI shield.

2. The method of claim 1, wherein:
applying one or more adhesion and/or dielectric layers comprises applying a dielectric layer along both the first side and the second side of the electrically-conductive fabric or film; and
the method includes attaching the stretchable and/or flexible EMI shield to the substrate such that the one or more components on the substrate are under the stretchable and/or flexible EMI shield generally between the substrate and the dielectric layer along the first side of the electrically-conductive fabric or film, whereby the dielectric layer along the first side of the electrically-conductive fabric or film inhibits the electrically-conductive fabric or film from directly contacting and electrically shorting the one or more components on the substrate that are under the stretchable and/or flexible EMI shield.

3. The method of claim 1, wherein:
applying one or more adhesion and/or dielectric layers comprises applying a dielectric layer along only the first side of the electrically-conductive fabric or film; and
the method includes attaching the stretchable and/or flexible EMI shield to the substrate such that the one or more components on the substrate are under the stretchable and/or flexible EMI shield generally between the dielectric layer and the substrate, whereby the dielectric layer inhibits the electrically-conductive fabric or film from directly contacting and electrically shorting the one or more components on the substrate that are under the stretchable and/or flexible EMI shield.

4. The method of claim 1, further comprising providing one or more resonators that are configured to be operable for virtually connecting the stretchable and/or flexible EMI shield to a ground plane without any physical electrical connection directly between the ground plane and the stretchable and/or flexible EMI shield.

5. The method of claim 4, wherein each of the one or more resonators includes an L-C resonator comprising an inductor and a capacitor.

6. The method of claim 5, wherein:
the method includes attaching the inductor to the stretchable and/or flexible EMI shield, and attaching the capacitor to the substrate; and/or
the inductor is an inductive pin, and the capacitor is a capacitive patch.

7. The method of claim 4, further comprising virtually connecting the stretchable and/or flexible EMI shield to the ground plane by using the one or more resonators and without using any physical electrical connection directly between the ground plane and the stretchable and/or flexible EMI shield.

8. The method of claim 4, further comprising positioning the stretchable and/or flexible EMI shield over one or more components along a first side of a printed circuit board such that the one or more resonators virtually connect the stretchable and/or flexible EMI shield to a ground plane along a second side of the printed circuit board.

9. The method of claim 1, further comprising:
shaping the stretchable and/or flexible EMI shield to define a plurality of individual EMI shielding compartments, such that different components on the substrate are positionable in different EMI shielding compartments and are provided with EMI shielding by virtue of the EMI shielding compartments inhibiting the ingress and/or egress of EMI into and/or out of each EMI shielding compartment; and.
attaching the stretchable and/or flexible EMI shield to one or more portions of the substrate between at least two of the one or more components on the substrate.

10. The method of claim 1, further comprising:
bringing the stretchable and/or flexible EMI shield into contact with one or more electrically-conductive grounding contacts on the substrate; and/or
connecting a first electrically-conductive grounding contact of the substrate with a second electrically-conductive grounding contact of the stretchable and/or flexible EMI shield to thereby ground the stretchable and/or flexible EMI shield.

11. The method of claim 1, wherein the method includes using heat, pressure, a heat press, and/or ultrasound for shaping the stretchable and/or flexible EMI shield such that edges of the stretchable and/or flexible EMI shield extend downward toward and into contact with the substrate.

12. The method of claim 1, wherein:
the electrically-conductive fabric or film comprises one or more of the following: a stretchable, conformable, and/or flexible fabric, a single-sided electrically-conductive fabric, a metal plated fabric, and a silver plated stretchable nylon knit material; and
the one or more adhesion and/or dielectric layers comprise one or more of the following: insulation adhesive, thermoplastic polyurethane, hot melt adhesive, epoxy, and electrically non-conductive hot melt polyethylene vinyl acetate adhesive film.

13. The method of claim 1, wherein:
the electrically-conductive fabric or film comprises a silver plated nylon/spandex fabric, and the one or more adhesion and/or dielectric layers comprise an electrically non-conductive hot melt polyethylene vinyl acetate adhesive film; and/or
the stretchable and/or flexible shielding layer is configured to have an elongation greater than 250 percent in in a machine direction at three pound force per inch width.

14. A flexible electronic circuit comprising:
a flexible substrate;
one or more components on the flexible substrate; and
a stretchable and/or flexible electromagnetic interference (EMI) shield provided over the plurality of components, the stretchable and/or flexible electromagnetic interference (EMI) shield including one or more adhesion and/or dielectric layers along at least a first side and/or a second side of an electrically-conductive fabric or film;
wherein the stretchable and/or flexible EMI shield is positioned over the one or more components on the flexible substrate, whereby the stretchable and/or flexible EMI shield is operable for providing EMI shielding for the one or more components under the stretchable and/or flexible EMI shield.

15. The flexible electronic circuit of claim 14, wherein:
the electrically-conductive fabric or film comprises a silver plated nylon/spandex fabric, and the one or more adhesion and/or dielectric layers comprise an electrically non-conductive hot melt polyethylene vinyl acetate adhesive film; and/or
the stretchable and/or flexible shielding layer is configured to have an elongation greater than 250 percent in a machine direction at 3 pound force per inch width.

16. The flexible electronic circuit of claim 14, further comprising one or more resonators coupled to the stretchable and/or flexible EMI shield, and wherein:
the substrate comprises a printed circuit board including a first side including the one or more components and a second side including a ground plane; and
the stretchable and/or flexible EMI shield is positioned over the one or more components along the first side of the printed circuit board; and
the one or more resonators virtually connect the stretchable and/or flexible EMI shield to the ground plane along the second side of the printed circuit board.

17. The flexible electronic circuit of claim 16, wherein each of the one or more resonators includes an L-C resonator comprising an inductor and a capacitor, and wherein:
the inductor is attached to the stretchable and/or flexible EMI shield, and the capacitor is attached to the printed circuit board; and/or
the inductor is an inductive pin, and the capacitor is a capacitive patch.

18. The flexible electronic circuit of claim 14, wherein:
the substrate includes one or more electrically-conductive grounding contacts in contact with the stretchable and/or flexible EMI shield to thereby ground the stretchable and/or flexible EMI shield; and/or
the substrate includes a first electrically-conductive grounding contact connected with a second electrically-conductive grounding contact of the stretchable and/or flexible EMI shield to thereby ground the stretchable and/or flexible EMI shield.

19. A shield suitable for use in providing electromagnetic interference (EMI) shielding for one or more components on a substrate, the shield comprising:
an electrically-conductive fabric or film including a first side and a second side; and
one or more adhesion and/or dielectric layers along at least the first side and/or the second side of the electrically-conductive fabric or film;
wherein the shield further comprises:
one or more resonators configured to be operable for virtually connecting the shield to a ground plane without any physical electrical connection directly between the ground plane and the shield; and/or
an electrically-conductive grounding contact connectible with an electrically-conductive grounding contact of the substrate to thereby ground the shield;
whereby the shield is positionable over the one or more components on the substrate such that the shield is operable for providing EMI shielding for the one or more components under the shield.

20. The shield of claim 19, wherein:
the electrically-conductive fabric comprises a silver plated nylon/spandex fabric; and the one or more adhesion and/or dielectric layers comprise an electrically non-conductive hot melt polyethylene vinyl acetate adhesive film; and/or
the stretchable and/or flexible shielding layer is configured to have an elongation greater than 250 percent in a machine direction at three pound force per inch width; and/or
the one or more resonators comprise a plurality of L-C resonators each including an inductor and a capacitor, wherein the shield is positioned relative to a printed circuit board such that one or more components along a first side of the printed circuit board are under the shield and such that the plurality of L-C resonators virtually connect the shield to a round plane along a second side of the printed circuit board.
